(19) United States
(12) Patent Application Publication
(10) Pub. No.: US 2009/0234598 A1
(43) Pub. Date: Sep. 17, 2009

(54) Temperature Controller

(75) Inventors: Lennart Ängquist, Enköping (SE); Magnus Callavik, Stocksund (SE); Gerhard Brosig, Vasteras (SE); Willy Hermansson, Vasteras (SE); Per Halvarsson, Vasteras (SE); Stefan Johansson, Vasteras (SE); Bertil Nygren, vasteras (SE); Gunnar Russberg, Vasteras (SE); Jan R. Svensson, Vasteras (SE)

Correspondence Address: VENABLE LLP, P.O. BOX 34385, WASHINGTON, DC, 20043-9998, US

(73) Assignee: ABB RESEARCH LTD., Zurich (CH)

(21) Appl. No.: 12/281,993

(22) PCT Filed: Mar. 6, 2006
(86) PCT No.: PCT/SE2006/000290

§ 371 Date: Feb. 9, 2009

(51) Int. Cl. G01R 31/36; G01N 27/27; H02J 7/00

(52) U.S. Cl. 702/63; 324/427; 320/128

(57) ABSTRACT

A charge controller of a high temperature battery for a power compensator of an electric power transmission line. The charge controller includes a sensor and a processor including a memory module. The charge controller includes a virtual battery model of the battery.

### TECHNICAL FIELD

The present invention concerns power compensation of a high voltage transmission line. By a transmission line should be understood a conductor for electric power transmission or distribution line within the range of 3 kV and upwards, preferably in the range of 10 kV and upwards. Especially the invention concerns an apparatus for providing a exchange of electric power on a high voltage transmission line. The apparatus comprises a voltage source converter (VSC) and an energy storage device. In particular the invention concerns the control of a battery means of the power compensator.

### BACKGROUND OF THE INVENTION

A plurality of apparatus and methods are known for compensation of reactive power on a transmission line. The most common apparatus comprises capacitor means or a reactor means capable of being controllably connected to the transmission line. The connecting means may preferably include a switch containing semiconducting elements. The semiconducting elements used in known applications commonly include a non-extinguishable element, such as a thyristor. These kinds of reactive power compensators are known as flexible alternating current transmission system (FACTS).

A known FACTS apparatus is a static compensator (STATCOM). A STATCOM comprises a voltage source converter (VSC) having an ac side connected to the transmission line and a dc side connected to a temporary electric power storage means such as capacitor means. In a STATCOM the voltage magnitude output is controlled thus resulting in the compensator supplying reactive power or absorbing reactive power from the transmission line. The voltage source converter comprises at least six self-commutated semiconductor switches, each of which shunted by a reverse parallel connected diode.

From U.S. Pat. No. 6,747,370 (Abe) a power compensation system using a high temperature secondary battery is previously known. The object of the compensation system is to provide an economical, high-temperature secondary battery based energy storage, which has a peak shaving function, a load leveling function and a quality stabilizing function. The known system comprises an electric power supply system, an electric load and an electric energy storage system including a high temperature secondary battery and a power conversion system. The battery is a sodium sulfur battery.

The system is arranged at an end of an electric power line. The load is a factory which under normal operating condition is provided with electric power supply from the power line. In case of power supply failure a high speed switch disconnects the power line and electric power is instead provided from the secondary battery. At the same time a back up generator is started. The known system having a sodium sulfur battery indicates that the power compensating system provides low power during a long time.

In one mode of operation the battery is providing extra energy to the factory during daytime while being recharged during night. In order to supply a factory with uninterruptible power there are arranged ten parallel connected battery units of 1280 V, each having a converter of 500 kW. In a further embodiment ten battery units are parallel connected in series with a 5 MW converter. In this embodiment a group of spare batteries is arranged for use with the high temperature battery circuit. In the event of a battery unit having a failure the failed unit is disconnected and the spare group is connected in parallel with the circuit.

From U.S. Pat. No. 6,924,623 (Nakamura) a method and device for judging the condition of a secondary battery is previously known. The object of the device and method is to provide the judgment more quickly and in more detail as compared with conventional methods and devices. The known method includes the steps of varying the charging current and calculating the quantity of electricity. The disclosed method is preferably directed to finding out the grade of degradation.

### SUMMARY OF THE INVENTION

An exemplary object of the present invention is to seek ways to improve the control a battery means for a power compensator of an electric transmission line.

This object is achieved according to the invention by a control apparatus characterized by the features in the independent claim 1 or by a method characterized by the steps in the independent claim 6. Preferred embodiments are described in the dependent claims.

According to the invention the control of the battery means of the power compensator is effected by a charge controller. The charge controller contains a model of the battery representing a virtual battery, a plurality of sensing means and calculating means including computer means and memory means. The virtual battery model comprises a model of the physical behavior of the battery as well as a memory containing historic data, such as the inner states of the battery, the distribution of chemical constituents, temperature, current and voltage, and the state of charge (SOC) properties.

A SOC-value is estimated by a current value provided from multiple calculations with the help of the virtual battery model of parallel observations. A first value of the voltage curve the battery unit is calculated from the measured current curve. The voltage curve is calculated with a plurality of parallel chosen current curves, each deviating a small amount from the measured current curve. Each such calculated voltage curve is compared with the actual measured voltage curve. When a close match between the calculated voltage curve and the measured voltage curve is achieved the input current curve for the matching calculation is chosen as the actual current curve.

According to an embodiment of the invention the power compensator comprises a system for controlling the performance and the action of the power compensator. The control system contains the charge controller for maintaining the charge and discharge respectively of the energy storage device. Since the charging and discharging behavior of a sodium/metal chloride battery is complicated the state of charge (SOC) of the battery cannot be measured but must be estimated. Also the current of the battery cannot be measured with a sufficient accuracy. The charge controller therefore comprises a SOC-module for estimating and predicting the state of charge of the battery.

A sodium/metal chloride battery cell comprises an electrolyte contained in a thin barrier of a ceramic material. Outside the barrier the battery cell comprises sodium being a first electrode. The second electrode comprises a pair of nickel plated copper electrodes to which is connected a metallic structure spreading into the electrolyte. When the battery is charged or discharged a reaction front is propagating inwardly from the ceramic barrier. Thus both the charging and discharging is propagating in the same direction and starting from the ceramic barrier. Resulting from a plurality of charging and discharging cycles there may be left inside the battery cell a plurality of areas defining power capacity areas and non-power capacity areas. Hence the SOC-module is capable to sum only the areas which represent power capacity. Thus the SOC value is the current integrated.

The SOC-module contains the virtual model of the battery. The virtual battery model contains a plurality of model parts representing specific relations of parameters and input values. Thus the virtual battery model comprises a measurement part model containing the relation between voltage, current, temperature and other parameters. Further the virtual battery model contains a part model for estimating the actual SOC-value containing memory means for historic data. The virtual battery model also contains a part model for predicting a future SOC-value containing a calculating model. Another part model is relating to historic data such as charging events, discharging events, the current history, recovery data and such.

The main objective of the virtual battery model is to produce a SOC-value which represents the remaining capacity of the battery. The SOC-value may be presented as a percentage value of full capacity of the battery. Another aim for maintenance of the battery comprises charge and discharge of the battery such that overcharges or undercharges never occur and such that the battery temperature is always kept within the allowable range.

By using the virtual battery model the SOC-module predicts also the SOC-value at a later point in time dependent on a desired power profile and duration. While using the capacity of the battery in a power compensation situation the predicted SOC-value and the battery state will tell if there is sufficient available energy for a predetermined mission. If for instance there is a power shortage in the transmission line the predicted SOC-value and battery state will tell if the capacity of the battery is sufficient for providing energy during a given period of time. This may happen after a power line failure and before power is provided again by other sources, such as start up period of a generator. If there is an excess of generated power on the transmission line, for instance due to a fault, the predicted SOC-value and battery state will instantly tell if the battery is capable to receive power from the transmission line. Hence the power compensator according to the invention is capable of both providing energy and receiving energy from the transmission line in a short time perspective, such as milliseconds, as well as in a longer time perspective, such as minutes.

In an embodiment of the invention the control system comprises a plurality of sensors for sensing voltage, current, temperature and other parameters. For electric power supply to these sensors the system comprises a power supply unit on each battery unit. The power supply unit is galvanic isolated from earth and comprises the same potential as the battery unit. The power supply may comprise a fuel cell, a solar cell, a thermo-electric element such as a peltier element and others. In an embodiment the power supply unit comprises battery means. For sending the information to the control system each sensor may communicate by help of a wireless system or an optical fiber. Each battery may also comprise a central communication device for communication of information.

According to an embodiment of the invention there is arranged on each galvanically isolated battery unit a communication module. The module comprises radio communication means, power supply and a plurality of sensing transducers. Also the communication module is galvanically isolated and thus achieving the same potential as the battery unit. The module may communicate within a wireless local area network, such as a WLAN or a Bluetooth network. The sensed values, such as voltage, current and temperature are preferably transmitted in digital form. To save power consumption the communication is arranged in short part of a time period. Thus the communication means need only be electrified during a small percentage of time. The communication may preferable take place within the 2 GHz band. The power supply comprises in one embodiment a back up battery and electric energy providing means. Such energy means may comprise any kind of generator configuration as well as a solar cell, peltier element, a fuel cell or other means.

The power compensator comprises according to the invention a voltage source converter and an energy storage device having a short circuit failure mode. By short circuit failure mode should be understood that in case of an interior failure of the energy storage device the electric circuit will be kept closed. The short circuit failure mode may be effected by the inner performance of the battery cell. It may also be effected by a controllable switch making a parallel loop with the battery cell.

Since the energy storage device must be capable of exchanging energy at all times there must be arranged for redundancy in case of a battery failure. Batteries having an open circuit failure mode must therefore be connected in parallel. Batteries having a short circuit failure mode may be connected in series thus reaching much higher voltage levels. In an embodiment of the invention the energy storage device comprises a high voltage battery containing a plurality of battery cells, each having a short circuit failure mode. A plurality of such batteries connected in series will always provide a closed circuit and thus be capable of providing electric energy even with a battery cell failure. A plurality of batteries connected in series will also be capable of providing energy at high voltage in the range of 6 kV and above.

A battery unit comprises a heat insulated box containing a plurality of series connected battery cells. The battery unit has two terminals comprising an electric circuit in the range of 1.5 kV. Connecting four such battery units in series will thus reach a voltage level of 6 kV. The battery unit comprises a local pipe loop for housing a heat transfer medium in the form of a fluid. The fluid may be a liquid medium as well as a gaseous medium.

A criteria for the function of the battery, e.g. to be able to store and release electric energy, is that the temperature inside the battery cell is kept between 270 and 340 C. At operation mode such as when the battery is being charged or discharged heat is generated within the battery. At idling mode, however, no heat is generated inside the battery. Thus at the idling mode heat has to be provided from outside the battery. At operation mode and small currents there is also provided for additional heat from outside the battery.

In an embodiment of the invention the power compensator comprises a temperature controller for maintaining the operation temperature of the battery unit. Thus the temperature controller is providing heat during the idling mode. The temperature controller contains a pipe network for providing a flow of the heat transfer medium through the battery units. The pipe network comprises a main pipe loop and at least one fluid moving unit, such as a fan or a pump. The pipe network includes the local pipe loop of each battery unit and provides a passageway for the heat transfer medium. The heat comprised in the heat transfer medium is transferred to the battery cells by convection.

According to an embodiment of the invention the local pipe loop comprises a first end for receiving a stream of a gaseous medium, and a second end for exhausting the gaseous medium. In an embodiment the gaseous medium comprises preferably air. Further the main pipe loop comprises an upstream side for providing hot air and a downstream side for receiving disposed air. Each first end of each local pipe loop is connected to the upstream side of the main pipe loop. Each second end of the each local pipe loop is connected to the downstream side of the main pipe loop. All connections between the main pipe loop and each local pipe loop comprises a connection pipe. The main loop comprises at least one fan and a heat providing means. In an embodiment of the invention the main pipe loop is grounded and thus exhibits the ground potential. Each local pipe loop exhibit the same potential as the battery unit housing the local pipe loop. In a further embodiment each connection pipe comprises a tube of a heat resisting and electric insulating material, such as a ceramic material.

According to an embodiment of the invention the plurality of series connected battery units form a battery string. Each battery unit comprises a high number of battery cells, each having a voltage in the range of 1.7 and 3.1 V. The cells are connected in series which results in the battery unit, which in one exemplary embodiment may have a voltage of some 1.5 kV. In one embodiment four such battery units are connected in series which results in a total voltage of 6 kV. However in other embodiments many batteries are connected in series giving a total voltage in the range of 30-100 kV. The main pipe loop therefore is galvanically separated from the battery string. The connection pipes must thus be made of an electric insulating, heat resistible material. In an embodiment the connection pipe comprises a ceramic tube.

In yet a further embodiment of the invention the temperature controller is also during the operation mode of the battery unit providing a cooled air for disposal of heat generated from the battery cells.

In a first aspect of the invention the object is achieved by a charge controller of a high temperature battery means for a power compensator of an electric power transmission line comprising sensing means and computer means including memory means, wherein the charge controller comprises a virtual battery model of the battery means for estimating the state of charge of the battery means. In a further embodiment the battery means comprises a high energy, high temperature sodium/metal chloride battery. In yet a further embodiment the virtual battery model comprises a model of the physical behavior of battery means. In still a further embodiment the virtual battery model comprises an estimation module for a plurality of calculations of the voltage curve outgoing from a measured curve value and a plurality of curves of the measured current curve adjusted with deviations. Yet in still a further embodiment the charge controller further comprises a measurement module, and a prediction module.

In a second aspect of the invention the object is achieved by a method of selecting an input current curve for estimating the state of charge of a high temperature battery means for a power compensator of an electric power transmission line, wherein the method comprises: providing a virtual battery model for calculating a voltage curve from a current curve, calculating a first voltage curve from a first current curve, calculating a second voltage curve from a second current curve, comparing the first and second voltage curve with a measured voltage curve, selecting the current curve, which calculation results in the best match of the voltage curve comparison, to be the input current curve. In a further embodiment of the method the first current curve represents the measured current curve. In another embodiment the second current curve comprises the measured current curve added with a deviation.

### BRIEF DESCRIPTION OF THE DRAWINGS

Other features and advantages of the present invention will become more apparent to a person skilled in the art from the following detailed description in conjunction with the appended drawings in which:

FIG. 1 is a principal circuit of a power compensator according the invention,

FIG. 2 is a side elevation of a part of an energy storage device comprising a plurality if battery units according to the invention,

FIG. 3 is a principal layout of a power compensator including a temperature controller and a charge controller,

FIG. 4 is the principal content of a SOC-module.

FIG. 5 is a parallel calculation of the voltage level.

FIG. 6 is side elevation of a energy storage device and a temperature controller, and

FIG. 7 is a further embodiment of the temperature controller.

### DESCRIPTION OF PREFERRED EMBODIMENTS

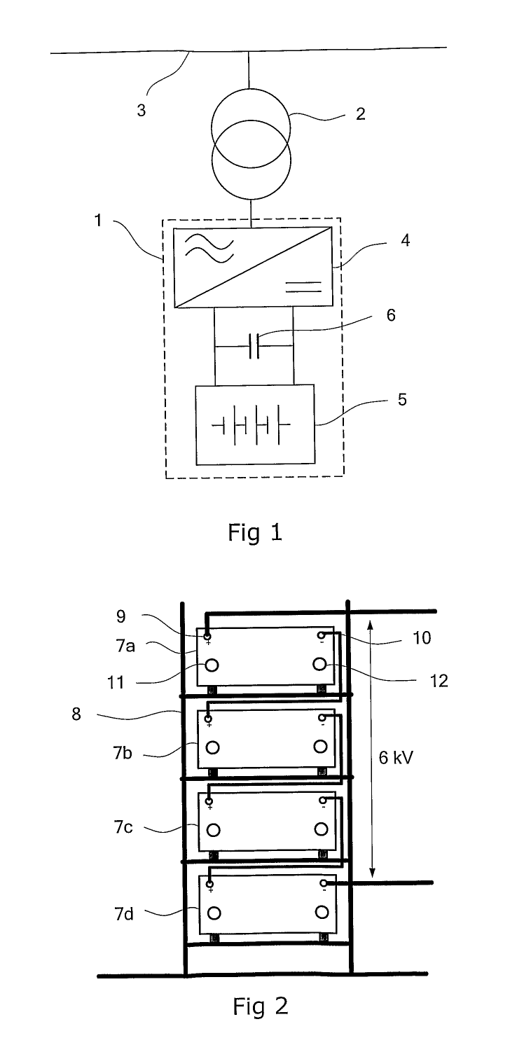

A principal circuit of a power compensator 1 connected to an electric power transmission line via a transformer 2 is shown in FIG. 1. The power compensator comprises a voltage source converter 4, a capacitor means 6 and an energy storage device 5. The voltage source converter comprises twelve selfcommutated semiconductor switches, each of which is shunted by a reverse parallel connected diode. The voltage source converter has an ac side connected to the transformer and a dc side connected to the capacitor means and the energy storage device.

The energy storage device comprises a plurality of series connected battery units 7. In the embodiment shown in FIG. 2 being a part of an energy storage device four battery units 7a-7d are arranged in a rack 8. Each battery unit has a positive terminal 9 and a negative terminal 10. In the embodiment shown each battery unit has a voltage of 1500 volts thus the energy storage device containing four batteries connected in series has a voltage level of 6 kV. However there may also be many more batteries in series resulting in a much higher voltage level.

The energy storage device comprises high energy, high temperature batteries containing sodium/metal chloride battery cells having an operating temperature in the range of 270-340° C. Each battery unit comprises a heat insulated box containing a plurality of series connected battery cells. In operation such as charging or discharging the batteries produce heat. At the idling mode heat from outside the battery must be provided for keeping the operational temperature conditions. The battery unit therefore contains a local pipe loop having a first opening 11 for receiving a stream of a gaseous medium, and a second opening 12 for exhausting the gaseous medium.

A sodium/metal chloride battery cell comprises an electrolyte contained in a thin barrier of a ceramic material. When the battery is charged or discharged a reacting front is propagating inwardly from the ceramic barrier. Thus both the charging and discharging is propagating in the same direction and starting from the ceramic barrier. Resulting from a plurality of charging and discharging cycles there may be left inside the battery cell a plurality of areas defining power capacity areas and non-power capacity areas.

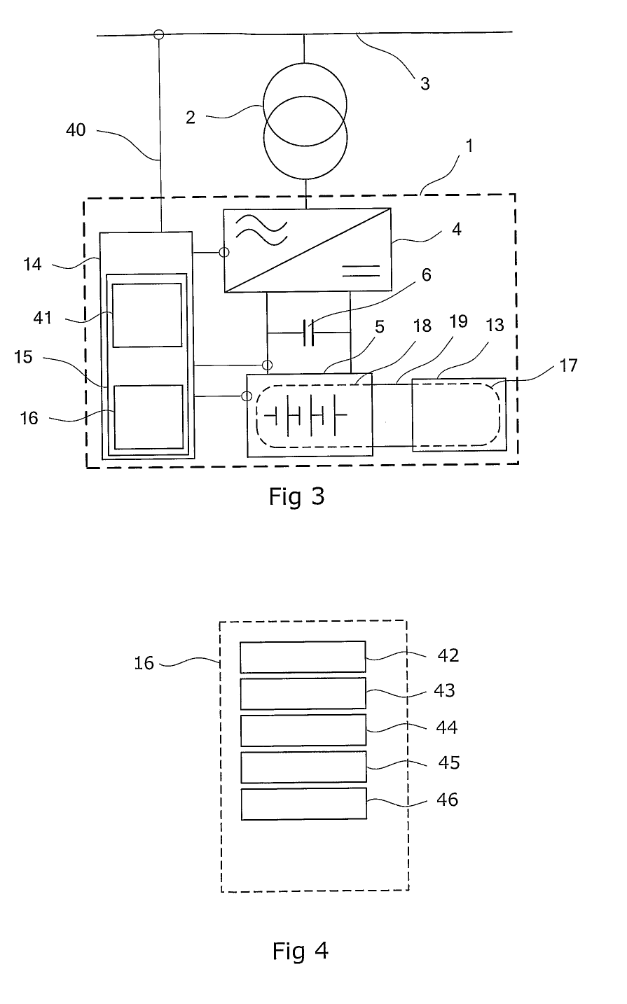

In further embodiment of the invention is shown in FIG. 3. In this embodiment the power compensator 1 comprises not only the voltage source converter 4 and the energy storage device 5 but also a temperature controller 13 and a control system 14 containing a plurality of sensor means 40, computer means 41 and a charge controller 15. The charge controller comprises a module 16 for estimating the state of charge of the battery. The temperature controller 13 comprises a pipe network for housing a heat transfer medium. The pipe network comprises a main pipe loop 17, the local loop 18 located in each battery unit and a plurality of connection pipes 19 connecting the main loop with the local loops. The temperature controller contains at least one heat providing means and a fluid moving unit for circulating the heat transfer medium in the pipe network. Hence by circulating the heat transfer medium through each battery heat is provided to the batteries by convection. In the embodiment shown the heat transfer medium comprises air and the fluid moving unit comprises a fan.

The SOC-module 16, which is a part of the charge controller 15, further comprises a plurality of parts as shown in FIG. 4. The SOC-module comprises a virtual battery model 42 of the sodium/metal chloride battery by which a SOC-value is calculated. The SOC-module further comprises a measuring module 43, an estimating module 44, a prediction module 45 and a temperature estimation module 46. By the temperature estimation module a future temperature of the battery depending on a future charge/discharge situation is calculated. This information may be sent to the temperature controller for pre-heating or pre-cooling the battery units.

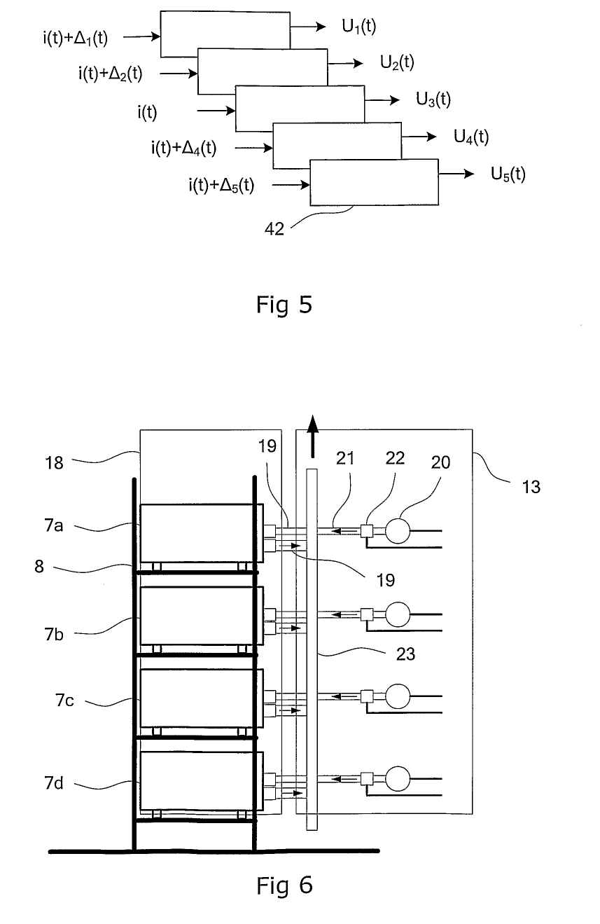

One way of estimating the actual current of the battery according to the invention is shown in FIG. 5. Outgoing from a start value, which may be a measured value of the current, the corresponding voltage is calculated from the virtual battery model. Since the measured current value contains uncertainties a parallel calculation is made with the virtual battery model for a plurality of current values deviating a small amount from the measured value. With a parallel calculation should be understood calculations of parallel events. Thus the actual calculations may be evaluated in series but still representing a parallel calculation. In the example shown in FIG. 5 five calculations are simultaneously made from parallel observed current values. A small deviation Δ=f(t) is defined and the voltage is calculated with i, i+Δ₁(t), i+Δ₂(t), . . . , i+Δₙ(t). The calculation thus results in n calculated voltage curves u₁(t)−uₙ(t), which are compared with the actual measured voltage value uₘ(t). The current curve iᵢ(t) resulting in the closest estimation of the actual voltage is chosen as the input current curve. Although the example shown in FIG. 5 comprises five parallel calculations any number of parallel calculations may be computed. The method described in the example above results in an adjustment of the offset error of the battery current measurement. By using the same adjustment technique also gain error of the current measurement can be detected.

In FIG. 6 the temperature controller 13 is schematically divided into a main pipe loop 13 and a common local pipe loop 18. In this embodiment the local pipe loop exhibits a high voltage potential while the main loop exhibits a ground potential. The connection pipes which connect the main pipe loop and the local pipe loop must not only exhibit an electric insulation but also withstand a fluid medium having a temperature of approximately 300° C. The main loop in this embodiment comprises a separate fan 20 and a pipe part 21 for each battery unit. Each pipe part comprises a heat providing element 22 for heat delivery to the battery unit. The heat delivery unit may comprise a resistive element for connection to a low voltage electric power source.

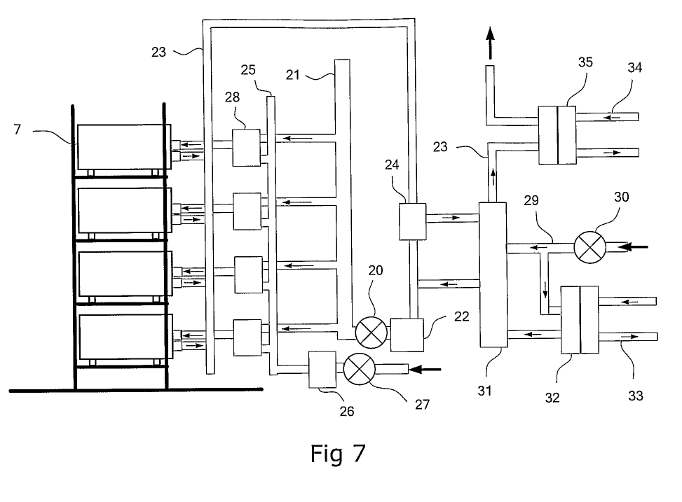

A further development of a temperature controller is shown in FIG. 7. In this embodiment the main loop of the temperature controller further comprises a common heating system 23 including a heater 22 and a common fan 20. According to this embodiment there is also provided for cooling of the battery units. Thus there is arranged a cooling loop 25 with a cooler and a common cooling fan 27. The provision of cooling or heating may be chosen by a switching valve 28. Also in the embodiment shown the heating system comprises an extension loop passing through a heat storage device 31. Further the system comprises a second loop 29 passing through a heat exchanger 32 for heat exchange with a second fluid system 33 which may comprise cooling water from the voltage source converter valves. The heating system also comprises a an extension loop passing through a second heat exchanger 35 for heat exchange with second heating system 34 which may be a heating system for a building.

Although favorable the scope of the invention must not be limited by the embodiments presented but contain also embodiments obvious to a person skilled in the art. For instance the SOC-module may comprise further measurement modules and computer means.

1-12. (canceled)

13. A charge controller of a high temperature battery for a power compensator of an electric transmission line, wherein the high temperature battery comprises a high energy, high temperature sodium/metal chloride battery, the charge controller comprising:
a module for estimating a state of charge of the battery, the module comprising a virtual battery model and an estimation module, wherein the estimation module
chooses a plurality of parallel current values, wherein each current value deviates a small amount from a measured current value,
calculates from the parallel current values corresponding voltage values with a virtual battery model,
compares the corresponding voltage values with an actual measured voltage value,
chooses a current value resulting in a closest estimation of the actual measured voltage value as an actual current value, and
estimates the state of charge of the battery by integrating the actual current value.

14. The charge controller according to claim 13, wherein the virtual battery model comprises a model of a physical behavior of the battery.

15. The charge controller according to claim 13, wherein the virtual battery model comprises a measurement part model comprising a relationship among voltage, current and temperature.

16. The charge controller according to claim 13, wherein the virtual battery model comprises a part model for estimating an actual SOC-value comprising a memory module configured to store historic data.

17. The charge controller according to 13, wherein the virtual battery model further comprises a part model comprising historic data.

18. The charge controller according to claim 17, wherein the historic data comprises charging events, discharging events, current history, and/or recovery data.

19. The charge controller according to claim 13, further comprising:
a measurement module; and
a prediction module.

20. A power compensator for an electric power transmission line, comprising:
a voltage source converter;
an energy storage device comprising a voltage battery comprising a short circuit failure mode in which in case of an interior failure of the energy storage device the electric circuit will be kept closed; and
a charge controller comprising a module for estimating a state of charge of the battery, the module comprising a virtual battery model and an estimation module, wherein the estimation module
chooses a plurality of parallel current values, wherein each current value deviates a small amount from a measured current value,
calculates from the parallel current values corresponding voltage values with a virtual battery model,
compares the corresponding voltage values with an actual measured voltage value,
chooses a current value resulting in a closest estimation of the actual measured voltage value as an actual current value, and
estimates the state of charge of the battery by integrating the actual current value

21. The power compensator according to claim 20, further comprising:
a temperature controller for maintaining a temperature of the power compensator within an operation range of the battery.

22. A method for estimating a state of charge of a high temperature battery comprising a high energy, high temperature sodium/metal chloride battery for a power compensator of an electric power transmission line, the method comprising:
selecting a plurality of parallel current values each deviating from a measured current value;
calculating from the parallel current values corresponding voltage values with a virtual battery model;
comparing corresponding voltage values with an actual measured voltage value;
selecting a current value resulting in a closest estimation of an actual measured voltage value as an actual current value; and
estimating a state of charge of the battery by integrating an actual current value.

23. A computer program product, comprising:
a computer readable medium; and
computer program instructions recorded in the computer readable medium and executable by a processor for carrying out a method for estimating a state of charge of a high temperature battery comprising a high energy, high temperature sodium/metal chloride battery for a power compensator of an electric power transmission line, the method comprising selecting a plurality of parallel current values each deviating from a measured current value, calculating from the parallel current values corresponding voltage values with a virtual battery model, comparing corresponding voltage values with an actual measured voltage value, selecting a current value resulting in a closest estimation of an actual measured voltage value as an actual current value, and estimating a state of charge of the battery by integrating an actual current value.

24. The computer program product according to claim 23, wherein the computer program instructions further comprise computer program instructions for providing the computer program instructions at least in part over a network.

25. The computer program product according to claim 23, wherein the computer program instructions further comprise computer program instructions for providing the computer program instructions at least in part over the internet.
